(19) United States
(12) Patent Application Publication
(10) Pub. No.: US 2025/0261348 A1
(43) Pub. Date: Aug. 14, 2025

(54) ELECTRONIC MODULE AND METHOD OF MANUFACTURING ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/046,516

(22) Filed: Feb. 6, 2025

(30) Foreign Application Priority Data
Feb. 14, 2024 (JP) 2024-020369

(51) Int. Cl. H05K 7/20; H05K 1/14; H05K 3/36; H05K 5/02

(52) U.S. Cl. CPC H05K 7/209; H05K 1/144; H05K 3/368; H05K 5/0247

(57) ABSTRACT

An electronic module includes a first board, a first heat generation part and a mold resin. The electronic module further includes a second board, and support members. A first heat radiation surface of the first board and a second heat radiation surface of the second board are exposed to an outside of the electronic module. According to such an electronic module, the electronic module can radiate heat from both surfaces of the electronic module and hence, it is possible to provide the electronic module that can increase heat radiation property compared to the conventional electronic module. Further, in manufacturing the electronic module, a pressing force can be applied to sides opposite to portions where the first and second boards are brought into contact with the support members and hence, the first heat radiation surface and the second heat radiation surface can be brought into close contact with a molding die.

### CROSS REFERENCE TO RELATED APPLICATIONS

This application claims priority to Japanese Patent Application No. 2024-20369, filed on Feb. 14, 2024, which is expressly incorporated herein by reference in its entirety.

### TECHNICAL FIELD

The present invention relates to an electronic module and a method of manufacturing an electronic module.

### BACKGROUND ART

Conventionally, there has been known an electronic module that includes: a board; a heat generation part (for example, a semiconductor chip such as a MOSFET or the like) that is disposed on the board; and a mold resin that seals a surface of the board on a side where the heat generation part is disposed and the heat generation part, wherein a surface of the board on a side opposite to the side where the heat generation part is disposed is exposed to the outside of the electronic module (for example, see patent literature 1).

In such a conventional electronic module, the surface of the board on the side opposite to the side of the board where the heat generation part is disposed is exposed to the outside of the electronic module and hence, heat generated from the heat generation part can be easily radiated to the outside of the electronic module via the board.

### PRIOR ART LITERATURE

### Patent Literature

[Patent Literature 1] WIPO 2020/208741

### SUMMARY OF INVENTION

### Technical Problem

A representative heat generation part in an electronic module is an electronic element. The study relating to electronic elements has been rapidly progressing recently and, for example, a next generation electronic element that uses SiC, GaN or the like as a semiconductor material has been put into practice. Such an electronic element enables downsizing (eventually high packaging) of the electronic element. On the other hand, with respect to these electronic elements, it is necessary to pay more attention to heat radiation property. Accordingly, in the technical fields of the electronic module, there has been a demand for increasing heat radiation property of an electronic module.

As the configuration for increasing heat radiation property of an electronic module, a configuration is considered where an electronic module includes an additional board (second board) that is disposed away from a conventionally existing board (first board). In the electronic module having such a configuration, it is possible to use a member that transfers heat generated from a heat generation part disposed on the first board to the second board, and it is also possible to arrange the heat generation parts on the first board and the second board in a distributed manner. Accordingly, the electronic module having the above-mentioned configuration can radiate heat from both surfaces of the electronic module and hence, heat radiation property can be enhanced compared to a conventional electronic module.

To manufacture the above-mentioned electronic module, it is necessary to form a mold resin so as to protect the internal structure of the electronic module. The mold resin is formed by using a molding die. In the conventional method of manufacturing a conventional mold, a means is adopted where support pins are mounted on a molding die, and the support pins press constitutional elements (for example, pin terminals) that are brought into contact with a board and protrude toward a side where the heat generation part is disposed. By adopting such a method, a surface (heat radiation surface) on a side opposite to a side of the board where the heat generation parts are disposed can be brought into close contact with the molding die thus preventing the adhesion of the resin to the heat radiation surface.

However, in a case of manufacturing an electronic module that includes two boards and radiates heat from both surfaces of the electronic module, since the boards exist on both surfaces of the electronic module and hence, unlike the conventional method, it is impossible to directly press the constitutional elements that protrude from the board.

The present invention has been made in view of the above-mentioned drawbacks, and it is an object of the present invention to provide an electronic module capable of making heat radiation property higher than a conventional electronic module, and also capable of preventing the adhesion of a resin to a heat radiation surface of a board. It is another object of the present invention to provide a method of manufacturing such an electronic module.

### Solution to Problem

An electronic module according to the present invention is an electronic module that includes: a first board; a first heat generation part that is disposed on the first board; and a mold resin that is configured to seal a surface of the first board on a side where the first heat generation part is disposed and the first heat generation part. The electronic module further comprises: a second board that is disposed on a side where the first heat generation part of the first board is disposed in a state where the second board is spaced apart from the first board and the first heat generation part; and a support member that is disposed between the first board and the second board, and is brought into contact with both the first board and the second board. A first heat radiation surface of the first board on a side opposite to a side where the first heat generation part is disposed, and a second heat radiation surface of the second board on a side opposite to a first board side are exposed to an outside of the electronic module.

A method of manufacturing an electronic module according to the present invention is a method of manufacturing the electronic module according to the present invention. The method includes: a preparation step of preparing an unsealed electronic module that includes the first board, the first heat generation part, the second board, and the support member; an arrangement step of arranging the unsealed electronic module in a molding die, applying a pressing force to a portion of the first heat radiation surface that corresponds to a back surface of a portion to which the first board and the support member are brought into contact, and applying the pressing force to a portion of the second heat radiation surface that corresponds to a back surface of a portion to which the second board and the support member are brought into contact thus bringing the first heat radiation surface and the second heat radiation surface into close contact with the molding die; and a molding step of forming the mold resin by filling an inside of the molding die with a resin.

### Advantageous Effects of the Present Invention

The electronic module according to the present invention includes: the second board that is disposed on the side where the first heat generation part of the first board is disposed in a state where the second board is spaced apart from the first board and the first heat generation part. Further, the first heat radiation surface that is the surface of the first board on the side opposite to the side where the first heat generation part is disposed, and the second heat radiation surface that is the surface of the second board opposite to the first board side are exposed outside of the electronic module. Accordingly, the present electronic module can radiate heat from both surfaces and hence, it is possible to provide the electronic module that can increase heat radiation property compared to the conventional electronic module.

Further, the electronic module according to the present invention includes the support member that is disposed between the first board and the second board and is brought into contact with both of the first board and the second board. According to the electronic module of the present invention, in manufacturing the electronic module, a pressing force can be applied to the side opposite to the portion where the first board and the support member are brought into contact with each other and the side opposite to the portion where the second board and the support member are brought into contact with each other and hence, the first heat radiation surface and the second heat radiation surface can be brought into close contact with the molding die. As a result, according to the electronic module of the present invention, the adhesion of a resin to the heat radiation surfaces of the boards can be prevented.

Accordingly, the electronic module according to the present invention becomes an electronic module that can increase its heat radiation property higher than heat radiation property of a conventional electronic module, and also can prevent the adhesion of a resin to a heat radiation surface of a board.

The method of manufacturing an electronic module according to the present invention includes: the preparation step of preparing the unsealed electronic module that includes the first board, the first heat generation part, the second board, and the support member. The method of manufacturing an electronic module according to the present invention also includes the arrangement step of arranging the unsealed electronic module in the molding die, applying a pressing force to the portion of the first heat radiation surface that corresponds to the back surface of the portion to which the first board and the support member are brought into contact, and applying the pressing force to the portion of the second heat radiation surface that corresponds to the back surface of the portion to which the second board and the support member are brought into contact thus bringing the first heat radiation surface and the second heat radiation surface into close contact with the molding die. Accordingly, the method of manufacturing an electronic module according to the present invention becomes a method that enables the electronic module to increase its heat radiation property higher compared to the conventional electronic module and, at the same time, can suppress the adhesion of a resin to the heat radiation surface of the board.

### BRIEF DESCRIPTION OF DRAWINGS

FIG. 1 is a perspective view of an electronic module 1 according to an embodiment.

FIG. 2A to FIG. 2C are external appearance views of the electronic module 1 according to the embodiment. FIG. 2A is a plan view of the electronic module 1. FIG. 2B is a left side view of the electronic module 1. FIG. 2C is a bottom view of the electronic module 1.

FIG. 3 is a perspective view of the internal structure of the electronic module 1 according to the embodiment. In FIG. 3, among constitutional elements of the electronic module 1, a mold resin 40 is not illustrated.

FIG. 4A to FIG. 4C are plan views illustrating the internal structure of the electronic module 1 according to the embodiment. FIG. 4A to FIG. 4C are plan views of the internal structure of the electronic module 1. In FIG. 4A, among the constitutional elements of the electronic module 1, a second board 20, a second heat generation part 22, a second spacer 25 and the mold resin 40 are not illustrated. In FIG. 4B, besides the constitutional elements not illustrated in FIG. 4A, a first heat transfer member 14, a first spacer 15, a first internal connection terminal 16, and external connection terminals 30, 35 are also not illustrated. In FIG. 4C, in addition to the constitutional elements that are not illustrated in FIG. 4B, a second heat transfer member 24, a second internal connection terminal 26 and external connection terminals 32a, 32b, 34, 36, 37 are also not illustrated. In FIG. 4C, a rectangular shape B that is an outer periphery of a center region is indicated by a broken line, and the center of gravity G of the first board 10 that is shared in common with the center of gravity of the center region is indicated by a dot. A region that is surrounded by the rectangular shape B is the center region, and a region outside the rectangular shape B is an outer peripheral region. A portion of the rectangular shape B overlaps with a profile of the first heat generation part 12 and hence, it is little difficult to recognize the rectangular portion B. However, a point F of the first heat generation part 12 that is remotest from the center of gravity G of the first board 10 overlaps with a vertex of the rectangular shape B.

FIG. 5A to FIG. 5D are side views illustrating the internal structure of the electronic module 1 according to the embodiment. FIG. 5A is a left side view of the internal structure of the electronic module 1. FIG. 5B is a view illustrating support members 18 and areas in the vicinity of the support members 18 illustrated in FIG. 5A in an enlarged manner. FIG. 5C is a right side view of the internal structure of the electronic module 1. FIG. 5D is a view illustrating support members 28 and areas in the vicinity of the support members 28 in FIG. 5C in an enlarged manner. In FIG. 5A to FIG. 5D, among the constitutional elements of the electronic module 1, the mold resin 40 is not illustrated.

FIG. 6A to FIG. 6D are side views illustrating the internal structure of the electronic module 1 according to the embodiment. FIG. 6A is a left side view of the internal structure of the electronic module 1. FIG. 6B is a view illustrating a first heat transfer members 14 and areas in the vicinity of the first heat transfer members 14 in FIG. 6A in an enlarged manner. FIG. 6C is a right side view of the internal structure of the electronic module 1. FIG. 6D is a view illustrating second heat transfer members 24 and areas in the vicinity of the second heat transfer members 24 in FIG. 6C in an enlarged manner. In FIG. 6A to FIG. 6D, among the constitutional elements of the electronic module 1, the support members 18, 28, the external connection terminals 34, 37 and the mold resin 40 are not illustrated. Arrows H1 to H4 indicated by a broken line in FIG. 6B and FIG. 6D, indicate a mode of heat transfer (a mode of heat radiation) during an operation.

FIG. 7A and FIG. 7B are bottom plan views illustrating the internal structure of the electronic module 1 according to the embodiment. FIG. 7A and FIG. 7B are bottom plan views of the internal structure of the electronic module 1. In FIG. 7A, among the constitutional elements of the electronic module 1, the first board 10, the first heat generation part 12, the first spacer 15 and the mold resin 40 are not illustrated. In FIG. 7B, in addition to the constitutional elements not illustrated in FIG. 7A, the second heat transfer member 24, the second spacer 25, the second internal connection terminal 26, second external connection terminals 26, and external connection terminals 32a, 32b, 36 are also not illustrated.

FIG. 8A to FIG. 8C are side views illustrating a method of manufacturing the electronic module according to the embodiment. FIG. 8A is a left side view illustrating a mode of a preparation step S10. FIG. 8B is a left side view illustrating a mode of an arrangement step S20. FIG. 8C is a left side view illustrating a mode of a molding step S30. In FIG. 8B, an arrow indicated by a symbol P illustrates portions to which a pressing force is applied in the arrangement step S20.

### DESCRIPTION OF EMBODIMENTS

Hereinafter, an electronic module and a method of manufacturing an electronic module according to the present invention are described based on an embodiment illustrated in drawings. The embodiment described hereinafter is not intended to limit the invention called for in claims. Further, it is not always the case that all of various constitutional elements and combinations of these constitutional elements described in the embodiment are indispensable as means to solve the problems of the present invention.

### Embodiment

### 1. Electronic Module 1 According to Embodiment

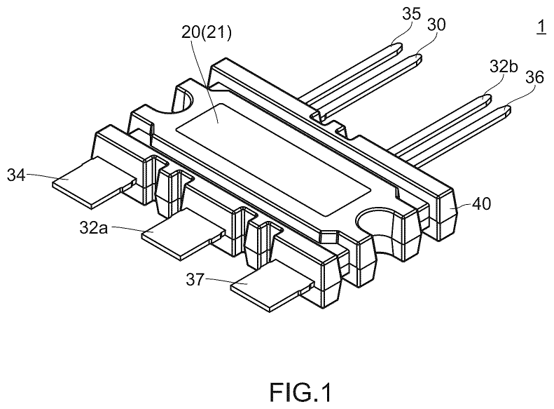

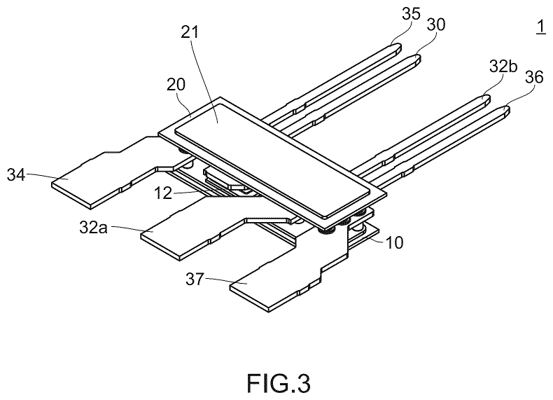

As illustrated in FIG. 1 to FIG. 8A to FIG. 8C, an electronic module 1 according to the embodiment includes: a first board 10; a first heat generation part 12; a first heat transfer member 14; a first spacer 15; a first internal connection terminal 16; support members 18, 28, a second board 20; a second heat generation part 22; a second heat transfer member 24; a second spacer 25; a second internal connection terminal 26; external connection terminals 30; 32a, 32b, 34, 35, 36, 37, and a mold resin 40. The electronic module 1 may include constitutional elements other than the above-mentioned constitutional elements. Hereinafter, the respective constitutional elements are described.

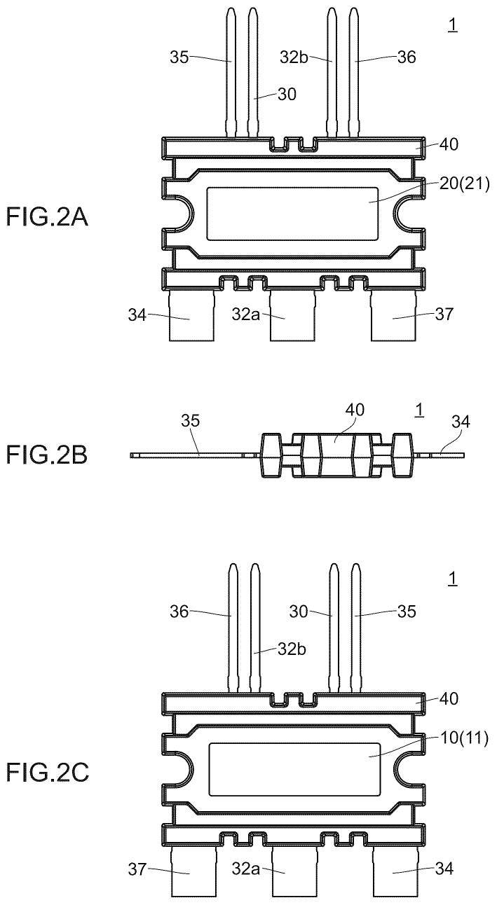

The first board 10 is a board on which the first heat generation part 12 is disposed. The first board 10 is a board having the structure where a copper plate is disposed on both surfaces of a ceramic plate (for example, DCB board). A first heat radiation surface 11 of the first board 10 on a side opposite to a side where the first heat generation part 12 is disposed is exposed to the outside of the electronic module 1 (outside of the mold resin 40) (see FIG. 2C). The first board 10 is electrically connected with a first drain electrode (first second electrode, described later) of the first heat generation part 12.

In this specification, the expression “electrically connected” includes not only a case where electrically conductive portions of the constitutional elements are directly brought into contact with each other but also a case where the electrically conductive portions of the constitutional elements are brought into contact with each other by way of other conductive constitutional elements (for example, solder or spacer).

The first heat generation part 12 is disposed on the first board 10. In this specification, the term “heat generation part” means an electronic part from which heat is generated when the electronic part is used (when electricity is supplied to the electronic part). As the heat generation part, an electronic element (typically a semiconductor chip), a resistor, a coil and a capacitor can be exemplified. However, the heat generation part is not limited to the above-mentioned parts.

The first heat generation part 12 is a vertical electronic part that includes a first first electrode and a first second electrode. Here, “first first electrode” means a first electrode of a first heat generation part, and “first second electrode” means a second electrode of a first heat generation part. In this specification, “vertical electronic part” means an electronic part where at least two kinds of electrodes (first electrode and second electrode) are disposed on a surface of the electronic part, and a surface on which the first electrode is disposed is a surface on a side opposite to a surface on which the second electrode is disposed. It may be also safe to say that “vertical electronic part” is a “an electronic part having an electrode on both surfaces”.

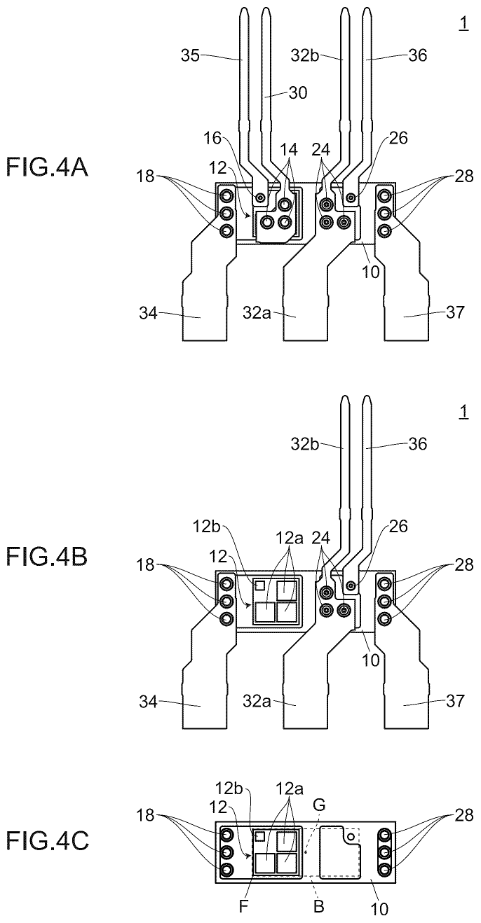

To be more specific, the first heat generation part 12 is a vertical metal-oxide semiconductor field-effect transistor (MOSFET) that includes: first source electrodes (first first electrodes) 12a disposed on a second board 20 side; a first drain electrode (first second electrode, not illustrated in the drawing) disposed on a first board 10 side; and a first gate electrode 12b disposed on the same side as the first source electrode 12a (see FIG. 4B). The first heat generation part 12 includes three first source electrodes 12a.

The first heat generation part 12 is a part that differs from the second heat generation part 22 in heat generation timing. In this specification, the condition “differs in heat generation timing” is satisfied when the timing that the heat generation of the first heat generation part is increased or decreased and the timing that the heat generation of the second heat generation part is increased or decreased when these heat generation parts are actually used do not agree with each other. It is preferred that the above-mentioned “heat generation timing” is “timing that the heat generation becomes maximum”. In this case, the above-mentioned technical feature may be also expressed such that “the first heat generation part 12 and the second heat generation part 22 are controlled such that the respective timings that the respective heat generation become maximum differ” at the time of using the electronic module 1. The electronic module 1 according to the embodiment constitutes a half bridge circuit and hence, the first heat generation part 12 is used to form a high side of the half bridge circuit and the second heat generation part 22 is used to form a low side of the half bridge circuit.

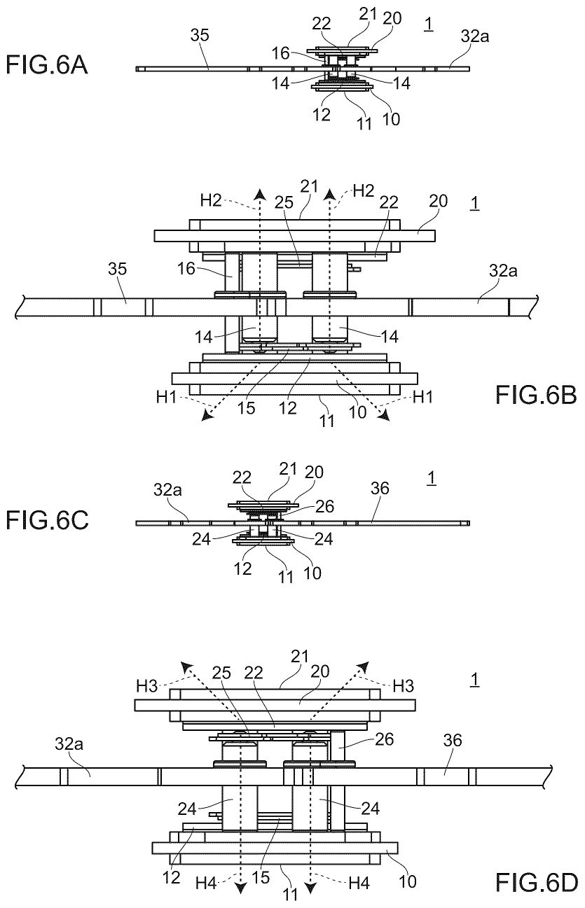

The first heat transfer member 14 is a member that transfers heat generated from the first heat generation part 12 to the second board 20 (see FIG. 6A and FIG. 6B). The first heat transfer member 14 is connected so that the first heat generation part 12 and the second board 20 perform the transaction of heat. The first heat transfer member 14 is an approximately columnar member where a main portion is integrally formed. With respect to the first heat transfer member, the expression “connected such that the transaction of heat can be performed” includes not only a case where the first heat transfer member is directly brought into contact with a target member but also a case where the first heat transfer member is connected with the target member via a different member (for example, solder or spacer). It is preferred that the above-mentioned “another member” is made of a material having favorable thermal conductivity (for example, metal material). The same goes for the second heat transfer member.

In this specification, a mode of heat transfer (a mode of heat radiation) relating to the first heat generation part 12 in the electronic module 1 is described with reference to FIG. 6B. The first heat generation part 12 is disposed on the first board 10. Accordingly, heat generated from the first heat generation part 12 is radiated to the outside of the electronic module 1 via the first board 10 (see an arrow H1).

The electronic module 1 includes the first heat transfer member 14 that transfers heat generated from the first heat generation part 12 to the second board 20. Accordingly, heat generated from the first heat generation part 12 is, besides from a path via the above-mentioned first board 10, radiated to the outside of the electronic module 1 also via a path via the first heat transfer member 14 and the second board 20 (see an arrow H2)

The first heat transfer member 14 is made of a material having conductivity, and, is electrically connected with an electrode of the first heat generation part 12. That is, it is safe to say that the first heat transfer member 14 also has a function of an internal connection terminal that exists in the electronic module 1 and is used for electrical transaction. The first heat transfer member 14 is electrically connected with the first source electrode (first first electrode) 12a. The electronic module 1 includes three first heat transfer members 14 corresponding to a state where the first heat generation part 12 has three first source electrodes 12a. An end portion of the first heat transfer member 14 on a side opposite to a first heat generation part 12 side is electrically connected with a wiring pattern of the second board 20.

The first spacer 15 is made of a material having conductivity and is a dish-shaped member that is interposed between the first source electrode 12a of the first heat generation part 12 and the first heat transfer member 14. Although not illustrated in the drawings, the first source electrodes 12a and the first spacer 15 are bonded to each other by bonding material having conductivity (for example, solder). Further, the first spacer 15 and the first heat transfer member 14 are also bonded to each other by a bonding material having conductivity.

The first internal connection terminal 16 is a member that exists in the electronic module 1, and is used for electrical transaction. The first internal connection terminal 16 is electrically connected with a first gate electrode 12b of the first heat generation part 12 and external connection terminal 35.

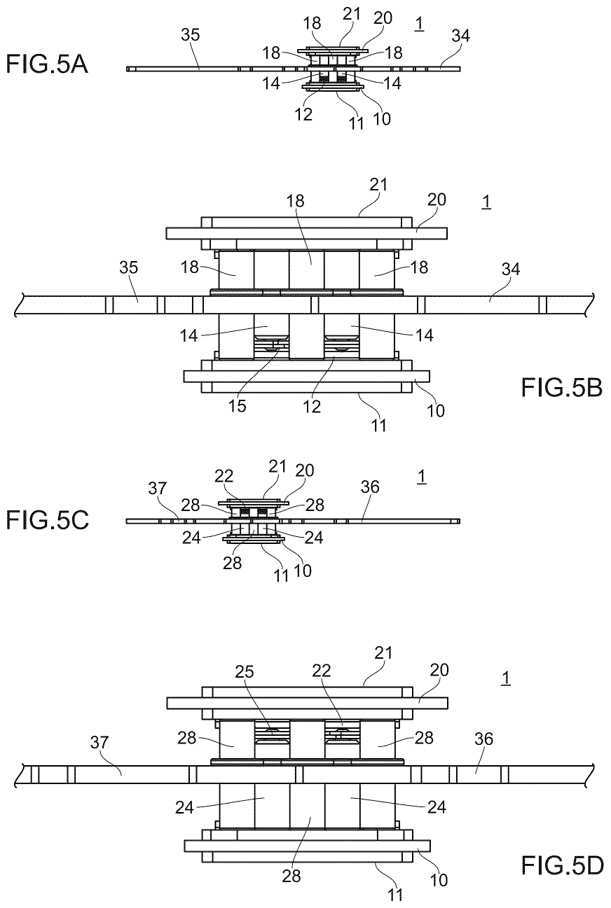

The support members 18, 28 are members that are disposed between the first board 10 and the second board 20 and are brought into contact with both of the first board 10 and the second board 20. (see FIG. 5A to FIG. 5D, particularly FIG. 5D). The electronic module 1 includes two or more support members 18, 28. In this embodiment, the electronic module 1 includes three support members 18 and three support members 28.

In a case where the electronic module 1 is viewed in a plan view using the surface of the first board 10 on which the first heat generation part 12 is disposed as the reference, assume a region that has an outer periphery formed of a rectangular shape B, has the center of gravity shared in common with the center of gravity G of the first board 10, and makes the outer periphery come into contact with a point F (a corner portion of the first heat generation part 12 in the electronic module 1) remotest from the center of gravity G of the first board 10 as a center region. Further, assume a region outside the center region as an outer peripheral region. In the electronic module 1, with respect to at least two support members out of the support members 18, 28 (in the electronic module 1, all of six existing support members 16, 28), end portions of the support members 16, 28 on a first board 10 side are brought into contact with the outer peripheral region (see FIG. 4C).

Further, the electronic module 1 is configured such that, in a case where the electronic module 1 is viewed in a plan view using the surface of the first board 10 as the reference, all support members 18, 28 are not aligned on one straight line. In performing the evaluation relating to the above-mentioned configuration, the evaluation is made with respect to not only either one of the support members 18 or the support members 28, but is made with respect to the entirety of the support members 18, 28.

The support members 18, 28 are made of a material having conductivity, and are electrically connected with other constitutional elements in the electronic module 1. The support members 18 are electrically connected with the first board 10 and the external connection terminal 34. The support members 28 are electrically connected with the second board 20 and the external connection terminal 37.

The second board 20 is a board that is disposed in a state where the second board 20 is spaced apart from the first board 10 and the first heat generation part 12 disposed on a side where the first heat generation part 12 of the first board 10 is disposed. With respect to the second board, the expression “a state where the second board is spaced apart from the first board and the first heat generation part” means a state where the second board is not directly brought into contact with the first board and the first heat generation part. Accordingly, so long as the second board is not directly brought into contact with the first board and the first heat generation part, even in a case where a constitutional element that is brought into contact with the second board is also brought into contact with the first board or the first heat generation part, it is safe to say that the second board is “in a state where the second board is spaced apart from the first board and the first heat generation part”.

The second board 20 is a board having the structure where a copper plate is disposed on both surfaces of a ceramic plate (for example, DCB board). A surface of the second board 20 on a side opposite to a first board 10 side is exposed to the outside of the electronic module 1 (see FIG. 1 and FIG. 2A). The second board 20 is electrically connected with the second drain electrode (the second second electrode, described later) of the second heat generation part 22.

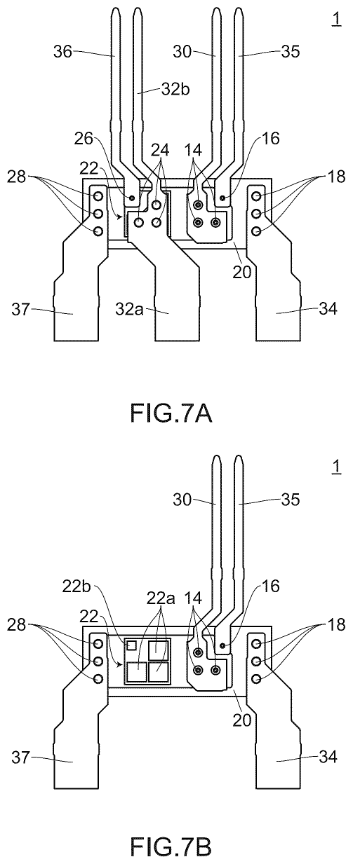

The second heat generation part 22 is disposed on a surface of the second board 20 on a first board 10 side. The second heat generation part 22 is a vertical electronic part that has a second first electrode and a second second electrode. Here, “second first electrode” means a first electrode of a second heat generation part, and “second second electrode” means a second electrode of a second heat generation part. To be more specific, the second heat generation part 22 is a vertical MOSFET that includes: second source electrodes (second first electrodes) 22a that are disposed on the first board 10 side; a second drain electrode (second second electrode not illustrated in the drawing) that is disposed on a second board 20 side; and a second gate electrode 22b that is disposed on the same side as the second source electrodes 22a (see FIG. 7B). The second heat generation part 22 has three second source electrodes 22a.

The second heat transfer members 24 are members that transfer heat generated from the second heat generation part 22 to the first board 10 (see FIG. 6C and FIG. 6D). The second heat transfer member 24 is an approximately columnar member that is connected with the second heat generation part 22 and the first board 10 so as to allow the transaction of heat between the second heat generation part 22 and the first board 10, and a main part of the member is formed as an integral body.

In this specification, as illustrated in FIG. 6D, a mode of heat transfer (a mode of heat radiation) relating to the second heat generation part 22 in the electronic module 1 is described. The second heat generation part 22 is disposed on the second board 20. Accordingly, heat generated from the second heat generation part 22 is radiated to the outside of the electronic module 1 via the second board 20 (see an arrow H3).

The electronic module 1 includes the second heat transfer member 24 that transfers heat generated from the second heat generation part 22 to the first board 10. Accordingly, heat generated from the second heat generation part 22 can be radiated to the outside of the electronic module 1 not only by way of a path via the above-mentioned second board 20 but also by way of a path via the second heat transfer member 24 and the first board 10 (see an arrow H4)

The second heat transfer member 24 is made of a material having conductivity, and, is electrically connected with an electrode of the second heat generation part 22. That is, it is safe to say that the second heat transfer member 24 also has a function of an internal connection terminal that exists in the electronic module 1 and is used for electrical transaction. The second heat transfer member 24 is electrically connected with the second source electrodes (second first electrodes) 22a. The electronic module 1 includes three second heat transfer members 24 corresponding to a state where the second heat generation part 22 has three second source electrodes 22a. An end portion of the second heat transfer member 24 on a side opposite to a second heat generation part 22 side is electrically connected with a wiring pattern of the first board 10.

The second spacer 25 is made of a material having conductivity and is a dish-shaped member that is interposed between the second source electrode 22a of the second heat generation part 22 and the second heat transfer member 24. Although not illustrated in the drawings, the second source electrodes 22a and the second spacer 25 are bonded to each other by bonding material having conductivity (for example solder). Further, the second spacer 25 and the second heat transfer member 24 are also bonded to each other by a bonding material having conductivity.

The second internal connection terminals 26 are members that exist in the electronic module 1, and are used for electrical transaction. The second internal connection terminal 26 is electrically connected with a second gate electrode 22b of the second heat generation part 22 and external connection terminal 36.

The external connection terminals 30, 32a, 32b, 34, 35, 36, 37 are members that are electrically connected with the constitutional elements of the electronic module 1 between the first board 10 and the second board 20, and at least one end of each external connection terminals 30, 32a, 32b, 34, 35, 36, 37 protrudes to the outside of the mold resin 40. The external connection terminal 30 is a detection terminal with respect to the first source electrode 12a of the first heat generation part 12. The external connection terminal 32a is a power terminal compatible to a large current. The external connection terminal 32b is a detection terminal with respect to the second source electrode 22a of the second heat generation part 22. The external connection terminals 32a, 32b are each formed of an integral body as a member.

The external connection terminal 34 is a power terminal that is electrically connected with the support member 18. The external connection terminal 35 is a control terminal that is electrically connected with the first internal connection terminal 16. The external connection terminal 36 is a control terminal that is electrically connected with the second internal connection terminal 26. The external connection terminal 37 is a power terminal that is electrically connected with the support member 28.

The mold resin 40 is a member that seals a surface of the first board 10 on a side where the first heat generation part 12 is disposed and the first heat generation part 12 (see FIG. 1 and FIG. 2A to FIG. 2C). Further, the mold resin 40 also seals a surface of the second board 20 on a side where the second heat generation part 22 is disposed and the second heat generation part 22.

### 2. Method of Manufacturing Electronic Module According to Embodiment

Hereinafter, the method of manufacturing an electronic module according to the embodiment is described. The method of manufacturing an electronic module according to the embodiment is the method of manufacturing the electronic module 1 according to the embodiment, and includes a preparation step S10, an arrangement step S20 and a molding step S30. The method of manufacturing an electronic module according to the embodiment may further include steps other than the above-mentioned steps. The respective steps are described hereinafter.

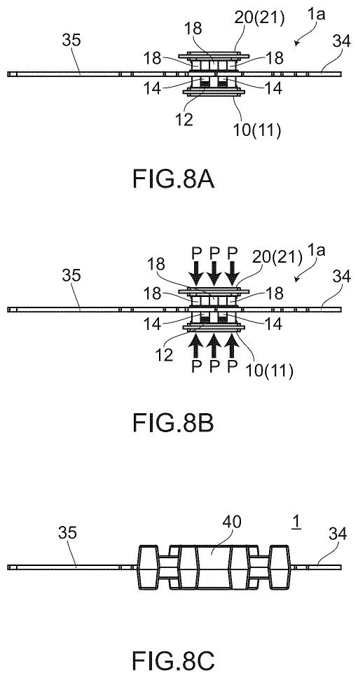

The preparation step S10 is a step of preparing an unsealed electronic module 1a that includes the first board 10, the first heat generation part 12, the second board 20, the support members 18, 28 (see FIG. 8A). The above-mentioned constitutional elements are the minimum necessary elements and hence, in this embodiment, the unsealed electronic module 1a includes all constitutional elements other than the mold resin 40 among the constitutional elements that the electronic module 1 includes.

The unsealed electronic module 1a prepared in the preparation step S10 may include constitutional elements that differ from the constitutional elements that the electronic module 1 includes in shape and state. For example, the external connection terminals 30, 32a, 32b, 34, 35, 36, 37 may be in a state where some or all of the external connection terminals 30, 32a, 32b, 34, 35, 36, 37 are formed integrally formed with a frame-shaped member (not illustrated in the drawing). In this case, it is necessary to cut away the external connection terminals 30, 32a, 32b, 34, 35, 36, 37 from the frame shaped member in the step that succeeds the molding step S30.

The arrangement step S20 is a step where the unsealed electronic module 1a is arranged in a molding die (not illustrated in the drawing). In the arrangement step S20, a pressing force is applied to: portions of the first heat radiation surface 11 that correspond to back surfaces of portions to which the first board 10 and the support members 18, 28 are brought into contact; and portions of the second heat radiation surface 21 that correspond to back surfaces of portions to which the second board 20 and the support members 18, 28 are brought into contact (hereinafter referred to as “portions to be pressed”) thus bringing the first heat radiation surface 11 and the second heat radiation surface 21 into close contact with the molding die (see FIG. 8B).

The above-mentioned portions to be pressed are portions to which a high pressing force is scheduled to be applied (portions that can withstand such a high pressing force). That is, the above-mentioned description does not exclude a case where a pressing force is applied to portions other than the portions to be pressed on the first heat radiation surface 11 and the second heat radiation surface 21. Accordingly, in performing the arrangement step S20, a pressing force may be applied to each individual pressing portions as illustrated in FIG. 8B, a pressing force may be applied to a linear or planar region that includes a plurality of portions to be pressed, or a pressing force may be applied by combining these two manners of applying the pressing force.

The molding step S30 is a step where the mold resin 40 is formed by filling the molding die with a resin (see FIG. 8C). By performing the molding step S30, the electronic module 1 can be manufactured.

### 3. Advantageous Effects of the Electronic Module 1 and the Method of Manufacturing an Electronic Module According to Embodiment

Hereinafter, advantageous effects of the electronic module 1 and the method of manufacturing an electronic module according to the embodiment are described.

The electronic module 1 according to the embodiment includes: the second board 20 that is disposed on a side of the first board 10 in a state where the first heat generation part 12 is disposed in a state where the second board 20 is spaced apart from the first board 10 and the first heat generation part 12. Further, the first heat radiation surface 11 that is the surface of the first board 10 on the side opposite to the side where the first heat generation part 12 is disposed, and the second heat radiation surface 21 that is the surface of the second board 20 on the side opposite to the first board 10 side are exposed to the outside of the electronic module 1. With such a configuration, according to the electronic module 1 of the embodiment, heat can radiated from both surfaces of the electronic module 1. Accordingly, the electronic module 1 according to the embodiment forms an electronic module that can increase heat radiation property compared to a conventional electronic module.

Further, the electronic module 1 according to the embodiment 1 includes the support members 18, 28 that are disposed between the first board 10 and the second board 20 and are brought into contact with both the first board 10 and the second board 20. According to the electronic module 1 of the embodiment, in manufacturing the electronic module 1, a pressing force is applied to a side opposite to the portions to which the first board 10 and the support members 18, 28 are brought into contact and portions on a side opposite to portions to which the second board 20 and the support members 18, 28 are brought into contact thus bringing the first heat radiation surface 11 and the second heat radiation surface 21 into close contact with the molding die. As a result, according to the electronic module 1 of the embodiment, it is possible to prevent the adhesion of the resin to the heat radiation surfaces of the boards.

Accordingly, the electronic module 1 according to the embodiment forms an electronic module that can increase heat radiation property compared to a conventional electronic module and, at the same time, can prevent the adhesion of a resin to the heat radiation surfaces of the board.

The electronic module 1 according to the embodiment includes the first heat transfer member 14 that transfers heat generated from the first heat generation part 12 to the second board 20. As a result, according to the electronic module 1 of the embodiment, heat generated from the first heat generation part 12 can be radiated not only by way of the first board 10, but also by way of the second board 20 via the first heat transfer member 14.

The electronic module 1 according to the embodiment includes two or more support members 18, 28. With respect to at least two support members 18, 28 out of the support members 18, 28, end portions of the support members 18, 28 on a first board 10 side are brought into contact with the outer peripheral region. According to the electronic module 1 of the embodiment, by arranging the support members 18 28 outside the first board 10, the first board 10 and the second board 20 can be stably supported in manufacturing the electronic module 1.

Further, in the electronic module 1 according to the embodiment 1, the support members 18, 28 are respectively made of a material having conductivity and, at the same time, are electrically connected with other constitutional elements of the electronic module 1. According to the electronic module 1 of the embodiment, it is possible to use the support members 18, 28 for the electric transaction in the electronic module 1 and hence, functions of constitutional elements can be collected whereby downsizing of the electronic module 1 can be realized.

Further, the electronic module 1 according to the embodiment includes: the second heat generation part 22 that is disposed on the surface of the second board 20 on a first board 10 side. With such a configuration, according to the electronic module 1 of the embodiment, the second heat generation part 22 can be also disposed on the second board 20 and hence, packing density can be increased. Further, according to the electronic module 1 of the embodiment, the first heat generation part 12 and the second heat generation part 22 are arranged on the first board 10 and the second board 20 in a distributed manner, heat radiation property can be further increased.

The electronic module 1 according to the embodiment includes the second heat transfer member 24 that transfers heat generated from the second heat generation part 22 to the first board 10. With such a configuration, according to the electronic module 1 of the embodiment, it is possible to radiate heat generated from the second heat generation part 22 by way of not only the second board 20 but also by way of the first board 10 via the second heat transfer board 10.

In the electronic module 1 according to the embodiment, the first board 10 and the second board 20 adopt the structure where a copper plate is disposed on both surfaces of a ceramic plate. As a result, according to the electronic module 1 of the embodiment, heat radiation property can be further increased by using the board having high heat conductivity.

The method of manufacturing the electronic module according to the embodiment includes the preparation step S10 of preparing the unsealed electronic module 1a that includes the first board 10, the first heat generation part 12, the second board 20, and the support members 18, 28. Further, the method of manufacturing the electronic module according to the embodiment includes the arrangement step S20 where the unsealed electronic module 1a is arranged in the molding die, and a pressing force is applied to: portions of the first heat radiation surface 11 that correspond to back surfaces of portions to which the first board 10 and the support members 18, 28 are brought into contact; and portions of the second heat radiation surface 21 that correspond to back portions of portions to which the second board 20 and the support members 18, 28 are brought into contact thus bringing the first heat radiation surface 11 and the second heat radiation surface 21 into close contact with the molding die. With such a configuration, the method of manufacturing the electronic module according to the embodiment can increase heat radiation property compared to a conventional electronic module and, at the same time, can prevent the adhesion of a resin to the heat radiation surfaces of the board.

Although the present invention has been described based on the above-mentioned embodiment heretofore, the present invention is not restricted to the above-mentioned embodiment. The present invention can be carried out in various modes without departing from the gist of the present invention. For example, the following modifications are also conceivable.

(1) The shapes, the numbers, the sizes, the positions and the like of the constitutional elements of the present invention are not limited to the constitutional element described in the above-mentioned description and the respective drawings, and these values can be suitably changed so long as the technical features of the present invention are not impaired.

To exemplify one example, although the number of the first heat generation part 12 is one in the above-mentioned embodiment, the present invention is not limited to such a configuration. The number of the first heat generation parts may be plural. The above-mentioned matter is also applicable to the second heat generation part in the same manner.

Further, to exemplify the other examples, although the number of the support member 18 and the number of the support members 28 are three respectively in the above-mentioned embodiment, the present invention is not limited to such a configuration. Although it is desirable that the number of the support members is two or more in total, the present invention can be realized even in the case where the number of the support members is one. Further, the arrangement and shapes of the support members 18, 28 in the above-mentioned embodiment are provided for an exemplifying purpose, and can be suitably set corresponding to the structure or the like of the electronic module.

(2) The electronic module according to the present invention may further include heat generation parts other than the first heat generation part (heat generation parts that do not have corresponding first heat transfer members) or other structures on the first board. Further, the electronic module according to the present invention may further include heat generation parts other than the second heat generation part (heat generation parts that do not have corresponding second heat transfer members) or other structures on the second board.

(3) The electronic module according to the present invention may not include the second heat generation part.

(4) The electronic module according to the present invention may not include the first heat transfer member. Further, even in a case where the electronic module according to the present invention includes the second heat generation part, the electronic module according to the present invention may not include the second heat transfer member.

(5) The electronic module according to the present invention may include neither the first spacer nor the second spacer.

(6) The functions of the respective external connection terminals 30, 32a, 32b, 34, 35, 36, 37 described in the above-mentioned embodiment are illustrated in an exemplifying purpose, and the present invention is not limited to such a configuration. The functions of the respective external connection terminals can be suitably set corresponding to the structure or the like of the electronic module.

(7) As the first heat generation part in the electronic module according to the present invention, a heat generation part other than the vertical MOSFET can be also used. As the heat generation part other than the vertical MOSFET, an electronic element other than the vertical MOSFET (diode, transistor, thyristor or like), a register, a coil, and a capacitor can be exemplified. The above-mentioned matters are also applicable to the second heat generation part.

1. An electronic module comprising:
a first board;
a first heat generation part that is disposed on the first board; and
a mold resin that is configured to seal a surface of the first board on a side where the first heat generation part is disposed and the first heat generation part, wherein
the electronic module further comprises:
a second board that is disposed on a side where the first heat generation part of the first board is disposed in a state where the second board is spaced apart from the first board and the first heat generation part; and
a support member that is disposed between the first board and the second board, and is brought into contact with both the first board and the second board, and
a first heat radiation surface of the first board on a side opposite to a side where the first heat generation part is disposed, and a second heat radiation surface of the second board on a side opposite to a first board side are exposed to an outside of the electronic module.

2. The electronic module according to claim 1, further comprising a heat transfer member that transfers heat generated from the first heat generation part to the second board.

3. The electronic module according to claim 1, wherein
The electronic module includes two or more said support members, and
in a case where the electronic module is viewed in a plan view using the surface of the first board on which the first heat generation part is disposed as the reference, assume a region that has an outer periphery formed in a rectangular shape, has a center of gravity thereof shared in common with a center of gravity of the first board, and makes the outer periphery come into contact with a point of the first heat generation part remotest from the center of gravity of the first board as a center region and a region disposed outside the center region as an outer peripheral region,
out of the support members, at least two support members are configured such that end portions of the support members on a first board side are brought into contact with the outer peripheral region.

4. The electronic module according to claim 1, wherein the support member is made of a material having conductivity, and is electrically connected with other constitutional elements in the electronic module.

5. The electronic module according to claim 1, further comprising a second heat generation part that is disposed on a surface of the second board on a first board side.

6. The electronic module according to claim 5, further comprising a second heat transfer member that transfers heat generated from the second heat generation part to the first board.

7. The electronic module according to claim 1, wherein the first board and the second board are respectively formed of a structure where a copper plate is disposed on both surfaces of a ceramic plate.

8. A method of manufacturing an electronic module for manufacturing the electronic module according to claim 1, the method comprising:
a preparation step of preparing an unsealed electronic module that includes the first board, the first heat generation part, the second board, and the support member;
an arrangement step of arranging the unsealed electronic module in a molding die, applying a pressing force to a portion of the first heat radiation surface that corresponds to a back surface of a portion to which the first board and the support member are brought into contact, and applying the pressing force to a portion of the second heat radiation surface that corresponds to a back surface of a portion to which the second board and the support member are brought into contact thus bringing the first heat radiation surface and the second heat radiation surface into close contact with the molding die; and
a molding step of forming the mold resin by filling an inside of the molding die with a resin.
